(19) United States
(12) Patent Application Publication
(10) Pub. No.: US 2025/0055209 A1
(43) Pub. Date: Feb. 13, 2025

(54) MASS-CONTACT MODULE FOR A CONTROL DEVICE, AND CONTROL DEVICE AND ASSEMBLY PROCESS

(71) Applicant: ZF CV Systems Europe BV, Brussels (BE)

(72) Inventors: Tobias Kortlang, Gehrden (DE); Lars Quernheim, Hannover (DE)

(21) Appl. No.: 18/928,624

(22) Filed: Oct. 28, 2024

Related U.S. Application Data
(63) Continuation of application No. PCT/EP2023/054163, filed on Feb. 20, 2023.

(30) Foreign Application Priority Data
Apr. 26, 2022 (DE) 10 2022 110 010.3

(51) Int. Cl. H01R 12/58; H01R 13/405; H01R 13/52; H01R 13/652

(52) U.S. Cl. CPC H01R 12/585; H01R 13/405; H01R 13/5216; H01R 13/652; H01R 2201/26

(57) ABSTRACT

A mass-contact module for a control device includes a press-in contact extending in a longitudinal direction and having a connector portion for forming an electrically conductive press-in connection to a circuit board and an end portion which is at a distance in the longitudinal direction and is configured to make contact with a contact surface. A supporting part is connected to the press-in contact and is configured to form a force-conducting connection between the circuit board and the press-in contact by forming a form-fitting and/or integral connection to the potting compound. A control device includes such a mass-contact module. An assembly method is for assembling a corresponding control device.

### CROSS-REFERENCE TO RELATED APPLICATIONS

This application is a continuation application of international patent application PCT/EP2023/054163, filed Feb. 20, 2023, designating the United States and claiming priority from German application 10 2022 110 010.3, filed Apr. 26, 2022, and the entire content of both applications is incorporated herein by reference.

### TECHNICAL FIELD

The disclosure relates to a mass-contact module for a control device. Such a mass-contact module includes a press-in contact which extends in a longitudinal direction and has a plug-in portion for forming an electrically conductive press-in connection to a circuit board, and an end portion, which is at a distance in the longitudinal direction and is configured to make contact with a contact surface.

### BACKGROUND

Such mass-contact modules or mass contacts, also referred to as grounding contacts, are generally known. They are used in control devices, such as for example control devices for motor vehicles, and are used for the solely electrically conductive connection of a circuit board to a metallic object. For this reason, the end portion of such a mass-contact module also has no connector or the like, but is configured solely to make contact with a contact surface. Via the use of mass-contact modules, it is intended to enhance the electromagnetic compatibility of control devices and the like.

According to the European EMC guideline, the electromagnetic compatibility designates the capability of an apparatus, an installation or a system to operate satisfactorily in the electromagnetic environment without itself causing electromagnetic interference in the process, which would be unacceptable for all apparatuses, installations or systems present in this environment. The basic protective requirements with which every electric device which is brought to the market must comply are derived therefrom. The protective requirements define that, firstly, the interference emissions for example of a control device must be so low that, for example, broadcast receivers or other operating media in the interference environment are not impermissibly affected. This is a limitation on the interference sources. Secondly, the disturbances to be expected and acting on the control device, such as fields, interference currents or interference voltages, should not impair its function.

The electromagnetic compatibility in vehicles having an electric drive or else in increasingly autonomously operated vehicles is of particular importance. Firstly, the safe operation of the control device, for example an engine control unit (ECU), may not be impaired by fields, interference currents or interference voltages. Secondly, such a control device may also not affect the remaining components of a motor vehicle, such as for example an electric motor or else diverse sensors and communication networks.

To enhance the electromagnetic compatibility of control devices for vehicles, in particular electric vehicles, mass-contact modules are known which, as a spring contact, produce an electrically conductive connection between the circuit board and a metallic housing part. Also known are mass contacts for such control devices, which are formed as a press-in contact. These are pressed into a corresponding recess in the circuit board, in order to enter into a force-conducting and electrically conductive connection with the circuit board. In order to prevent damage to such mass contacts as a result of vibrations, control devices have an electronics housing which has specific recesses for guiding the press-in contacts. The stylistic freedom of electronics housing and therefore the arrangement option of the corresponding mass contacts is, however, restricted.

In press-in connections of circuit boards and mass contacts or mass-contact modules of the type described at the beginning, it must be ensured that no movement occurs between the circuit board and the press-in contact. As a result of a movement between the press-in contact and the circuit board, for example as a result of shaking during operation, the transition resistance between the press-in contact and the circuit board can increase and failure of the connection results. To avoid such a movement between press-in contact and circuit board, guides in the electronics housing of control devices are known from the prior art, which are specifically integrated into the electronics housing for the mass contact and in a manner corresponding to its shape and arrangement. This highly restricts the configuration freedom of corresponding control devices and, in particular, does not permit any individual retrofitting of mass contacts. An individual ability to retrofit mass contacts is desirable in view of an extremely wide range of country-specific laws with respect to the requirements on control devices for motor vehicles.

With the aim of improving the conduction of force between the press-in contact and the circuit board, potting mass contacts via a potting compound is also known. Such potting compounds are, for example, PU potting compounds. These make only an inadequate connection to the metallic mass contact, so that moisture can enter at the interface between potting compound and mass contact. This leads to corrosion of the mass contact and finally to a lack of electrical conduction between circuit board and mass contact.

### SUMMARY

It is an object of the present disclosure to overcome at least one of the disadvantages known from the prior art. In particular, it is an object of the present disclosure is to specify a mass-contact module for a control device (ECU) which permits high configuration freedom of the control device and flexible retrofitting, wherein adequate safety and corrosion resistance of the mass-contact module must be ensured.

The disclosure achieves the aforementioned object in a first aspect via a mass-contact module for a control device. The mass-contact module includes: a press-in contact extending in a longitudinal direction; the press-in contact having a connector portion for forming an electrically conductive press-in connection to a circuit board and an end portion which is at a distance in the longitudinal direction and is configured to make contact with a contact surface; and, a supporting part connected to the press-in contact and configured to form a force-conducting connection between the circuit board and the press-in contact by forming at least one of a form-fitting and an integral connection to a potting compound.

In a mass-contact module of the type mentioned above, the disclosure proposes a supporting part which is connected to the press-in contact and is configured to form a force-conducting connection between the circuit board and the press-in contact by forming a force-fitting and/or integral connection to the potting compound. The press-in contact is thus held and guided securely in the supporting part. The necessity of a guide provided specifically for the press-in contact, for example in the electronics housing of a control device, is thus dispensed with. At the same time, as a result of forming a force-conducting connection between the circuit board and the press-in contact, a movement of the press-in contact relative to the circuit board is reliably prevented. Furthermore, the corrosion of the press-in contact is effectively avoided by the connection to the supporting part, since ultimately only the supporting part has an interface to the potting compound that is in contact with the environment, but not to the press-in contact. Thus, no moisture from the environment can enter at an interface between the press-in contact and the potting compound. The material of the supporting part can be matched here individually to that of the press-in contact, so that an ingress of liquid between the press-in contact and the supporting part can be avoided. Such a mass-contact module can be integrated simply in existing control devices as a result of the modular structure with a supporting part and a press-in contact, and is flexible with regard to the arrangement and number of mass-contact modules.

In the present case, a force-conducting connection designates a connection which permits forces to be conducted between the circuit board and the press-in contact and, in the event of vibrations or the like, prevents any movement of the press-in contact relative to the circuit board. It is intended also to be understood that the formation of a form-fitting and/or integral connection of the supporting part to the potting compound depends on the individual material pairing. Depending on the viscosity of the potting compound, this also gets into extremely small voids in the surface of the supporting part and thus ensures a form-fitting connection. The supporting part preferably includes a hard-elastic plastic. Optionally, the supporting part can also have undercuts into which the potting compound is introduced, so that a form-fitting connection is also formed on the macroscopic scale. In addition, depending on the material pairing, an integral connection arises as a result of covalent bonds, ionic bonds and van der Waals forces, wherein the connection can be effected in a manner chemically induced or thermally induced.

It can be preferable for the supporting part to have a guide portion and an anchoring portion projecting transversely to the longitudinal direction relative to the guide portion. The guide portion is configured for the connection to the press-in contact, and the anchoring portion is configured for the form-fitting connection to the potting compound. Via the guide portion, in particular bending loads acting on the press-in contact can be reduced. Via the anchoring portion projecting transversely to the longitudinal direction, a form-fitting connection of the supporting part to the potting compound is also ensured on the macroscopic scale. As a result, increased pull-off forces are needed to detach the mass-contact module from the potting compound. The guide portion preferably extends in the direction of the end portion, particularly preferably completely along the longitudinal extent of the press-in contact as far as the end portion.

The anchoring portion can preferably have an anchor plate and at least one force introduction element arranged between the anchor plate and the end portion. Such an anchor plate permits an improved and large-area introduction of force into the potting compound and in particular requires increased withdrawal forces to detach the supporting part from the potting compound. The force introduction elements arranged between the anchor plate and the end portion are intended here in particular to increase the support of the press-in contact with respect to bending loads and forces transversely to the longitudinal direction. Preferably, one or more force introduction elements are provided, wherein the force introduction elements are configured as supporting struts or wings, which are configured to taper in the direction of the end portion.

According to an embodiment, the supporting part is formed integrally with a connector bridge. The basic element of a connector bridge is normally a molding which is formed of hard-elastic plastic and in which one or more connectors or connector contacts are accommodated. The individual connectors are configured to form a signal connection and are insulated electrically from one another by the molding. The structure of a control device having such a connector bridge is more compact as a result of receiving a large number of connectors or connector contacts in the molding. As a result of the integral formation of the mass-contact module on such a connector bridge, the assembly is simplified further and the structure of a corresponding control device is further optimized. The arrangement of the connector bridge is limited in that the connector bridge having the connector contacts to form a signal connection must be arranged in the area of corresponding openings in the electronics housing, so that signals can be led to the circuit board of the control device and away from the latter via signal connections.

It can further be preferable for the supporting part to include a thermoplastic, in particular polybutylene terephthalate or polyamide. Thermoplastics, in particular polybutylene terephthalate or polyamide, are well suited to be connected to conventional potting compounds, such as in particular PU potting compounds. In particular, via such a material combination, the ingress of moisture at the interface of the supporting part and the potting compound is effectively reduced or prevented. Particularly preferably, the thermoplastic is a fiber-reinforced thermoplastic having a fiber proportion of at least 10%, preferably 20%. The mechanical and in particular also the thermal properties of the supporting part are improved further by an appropriate fiber proportion. Thus, the force-conducting connection of the press-in contact to the circuit board is improved further, and the supporting part can be configured to be more compact because of the improved mechanical properties of the material, so that installation space is saved. The fibers can preferably be glass fibers, natural fibers or ceramic fibers. The reinforcing fibers are preferably non-conductive.

According to a further embodiment, the supporting part is an electrical insulator. The electrical conduction of the mass-contact module is thus specifically carried out via the press-in contact, in particular deliberately via its end portion.

According to an embodiment, the end portion has a first leg and a second leg, which extend in the longitudinal direction and are movable or at least elastically deformable relative to one another transversely to the longitudinal direction, in order in each case to come into contact with a contact surface. Preferably, the legs are accordingly accommodated between two opposite contact surfaces or a cylindrical contact surface which, for example, is provided by a hole. Via a first leg and a second leg which each come into contact with a contact surface, the security of the mass-contact module is increased to the effect that even in the event of damage to one of the legs or shape and position deviations of same, electric conduction to the contact surface can still reliably be carried out at least via the respectively other leg. Preferably, a diecast housing of a control device has an appropriate hole, the diameter of which corresponds to the external spacing of the contact surfaces of the legs. The legs are preferably compressed as the mass-contact module is inserted and, following the insertion into the corresponding receiving hole, spring apart in such a way that each of the legs comes into contact with a respective wall section of the hole in the diecast housing in a contact area. The legs accommodated in the hole preferably spring transversely with respect to the longitudinal direction, in the direction of the contact surface, as a result of a movement or elastic deformation. This outwardly directed springing of the legs leads to a reliable connection of the legs and the contact surface, which is preferably formed by the wall of a hole.

It can be preferable for the supporting part to have a press-in opening and for the press-in contact to be configured to be connected to the supporting part by pressing into the press-in opening in a press-in direction. As a result of pressing the metallic press-in contact into the supporting part, which in particular consists of an insulator, a secure and play-free connection of the press-in contact and the supporting part is produced. This connection here is in particular form-fitting and prevents a relative movement of the press-in contact relative to the supporting part transversely to the press-in direction. It is further preferable for the press-in contact to have a number of retaining elements, which are configured to prevent a movement of the press-in contact relative to the supporting part counter to the press-in direction. The retaining elements are, for example, hooks or prongs which, in the event of a movement counter to the press-in direction, engage in the supporting part. More preferably, the press-in contact is configured to be connected to the supporting part by pressing in via ultrasonic embedding. During ultrasonic embedding, the connection quality is increased further as a result of ultrasound-induced partial melting of the supporting part.

According to an alternative embodiment, the supporting part is produced by an injection molding process, in which the press-in contact is laid in the injection molding tool and the press-in contact is overmolded for the production of the supporting part and the connection to the supporting part. Thus, the supporting part can be produced in only one process step and, at the same time, a connection of the supporting part to the press-in contact can be made. The production times for the mass-contact module are thus reduced. Furthermore, a reliable connection is ensured by the overmolding of the press-in contact with liquid injection molding compound, which prevents the penetration of moisture. Polymers that are capable of injection molding preferably here have a low viscosity, so that even extremely small voids are filled and the corrosion protection is ensured.

The disclosure has been described above in a first aspect with reference to a mass-contact module. In a second aspect, the disclosure achieves the object mentioned at the beginning via a control device (ECU) for a motor vehicle which includes an electronics housing, a circuit board arranged in the electronics housing, a potting compound, in which the circuit board is embedded, a metallic contact surface and at least one mass-contact module according to the first aspect of the disclosure. According to the second aspect, the disclosure further proposes that the mass-contact module is intended for the electrically conductive connection of the circuit board to the metallic contact surface, wherein the supporting part of the mass-contact module forms a force-conducting connection between the circuit board and the press-in contact by forming a form-fitting and/or integral connection to the potting compound. Via such a mass-contact module according to the first aspect of the disclosure, the control device (ECU) according to the disclosure according to the second aspect of the disclosure adopts the above-described advantages. Advantages and preferred embodiments according to the first aspect of the disclosure are likewise advantages and preferred embodiments of the control device (ECU) according to the second aspect of the disclosure and vice versa.

It can be preferable for the potting compound to include a thermosetting plastic, preferably polyurethane. Potting with thermosetting potting compounds can easily be automated. As opposed to thermoplastics, thermosetting plastics are chemically crosslinking and thus do not have to be kept above the melting temperature in order to remain free-flowing. The ability of thermosetting potting compounds to be processed is therefore advantageous as compared with thermoplastic potting compounds. Furthermore, thermosetting potting compounds are insulating and thus well suited for the use in control devices, in particular engine control devices.

According to an embodiment, the control device includes a hole with a wall which forms the contact surface, and preferably in addition an insertion bevel, which is configured to center the mass-contact module. The assembly of the control device is simplified by the centering. By providing the contact surface via the wall of the hole, the mass-contact module is additionally protected against forces transversely to the longitudinal direction. Particularly preferably, the hole can be formed in a diecast housing, which is configured to close the electronics housing.

According to an embodiment, the potting compound is configured for the form-fitting and integral connection to the supporting part. Via a form-fitting and an integral connection, the transmission of force between the supporting part and the potting compound is improved further and the penetration of moisture into the mass-contact module is reduced. As a result of an integral connection between the potting compound and supporting part, no moisture can enter the mass-contact module.

In a third aspect, the disclosure achieves the object mentioned above via an assembly method for assembling a control device, in particular a control device according to the second aspect of the disclosure, for a motor vehicle. The assembly method here includes the steps:
connecting a circuit board to an electronics housing,
providing at least one mass-contact module according to the first aspect of the disclosure,
pressing the press-in contact of the mass-contact module into a corresponding opening in the circuit board to form an electrically conductive connection, and
pouring a potting compound into the electronics housing to embed the circuit board, wherein the supporting part is at least partly embedded by the potting compound in order to form a force-conducting connection between the circuit board and the press-in contact.

As a result of the provision of a mass-contact module according to the first aspect of the disclosure and the embedding of the supporting part of this mass-contact module in a potting compound, the assembly process adopts the advantages explained at the beginning with reference to the first aspect of the disclosure. Advantages and preferred embodiments of the first aspect of the disclosure are likewise preferred embodiments and advantages according to the third aspect of the disclosure and vice versa.

### BRIEF DESCRIPTION OF DRAWINGS

The invention will now be described with reference to the drawings wherein:

FIG. 1 shows a control device according to the disclosure in a preassembled state in a perspective view;

FIG. 2 shows the control device according to FIG. 1 in an assembled state in a perspective view;

FIG. 3 shows a partly sectioned side view of the control device according to FIG. 2;

FIG. 4 shows a control device according to a second embodiment in a perspective view;

FIG. 5A shows a mass-contact module according to a first embodiment in a sectioned side view;

FIG. 5B shows the mass-contact module according to FIG. 5A in a side view;

FIG. 6A shows a mass-contact module according to a second embodiment in a sectioned side view;

FIG. 6B shows the mass-contact module according to FIG. 6A in a side view;

FIG. 7 shows a control device having a mass-contact module according to a third preferred embodiment in a sectioned side view;

FIG. 8A shows a mass-contact module for the control device according to FIG. 7 in a sectioned side view; and,

FIG. 8B shows the mass-contact module according to FIG. 8A in a side view.

### DETAILED DESCRIPTION

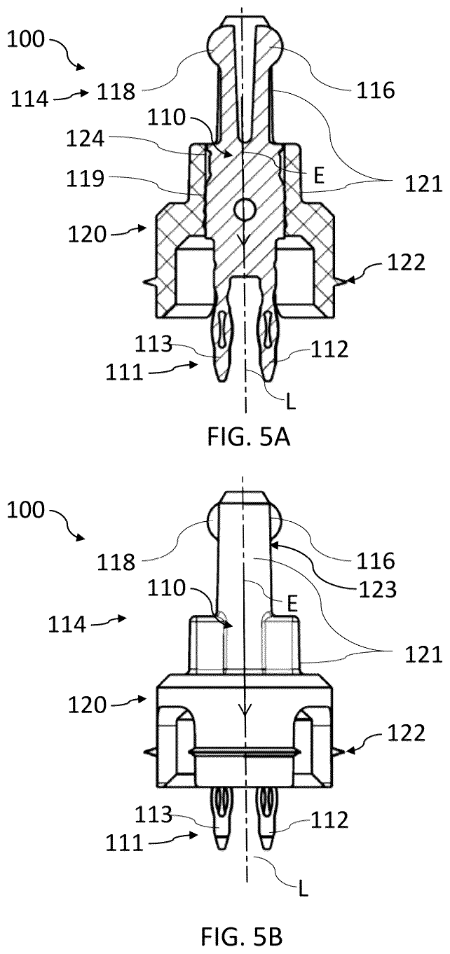

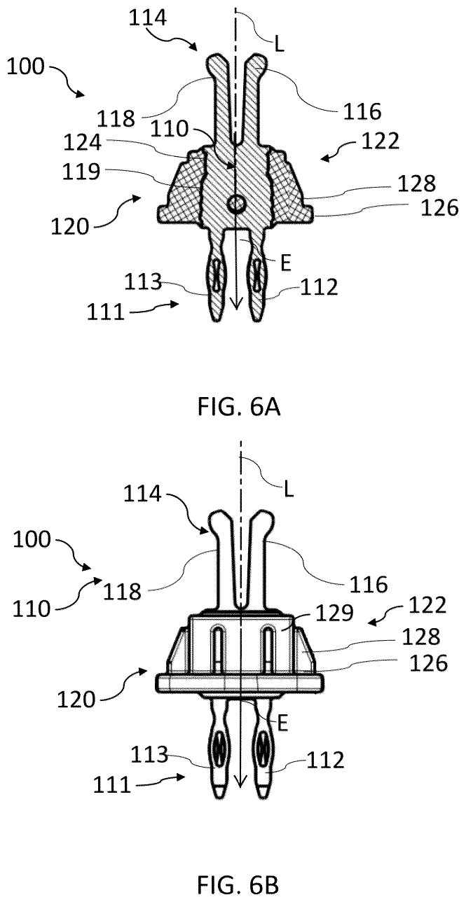

A control device 1000 for a motor vehicle, also referred to as ECU, includes an electronics housing 200, which in particular is a plastic housing. Arranged in the electronics housing 200 is a circuit board 300 which, in particular, is pressed into the electronics housing 200. The circuit board 300 has a first receptacle 302 and a second receptacle 304, which are configured to receive a first pin 112 (see FIGS. 5A to 6B) and a second pin 113 (see FIGS. 5A to 6B). Also pressed into the circuit board 300 is a connector bridge 400, which has a molding 410 and a total of three connectors 421, 422, 423 accommodated in the molding 410.

Furthermore, the control device 1000 has a mass-contact module 100. The mass-contact module 100 is configured to be introduced into the first receptacle 302 and the second receptacle 304 of the circuit board 300.

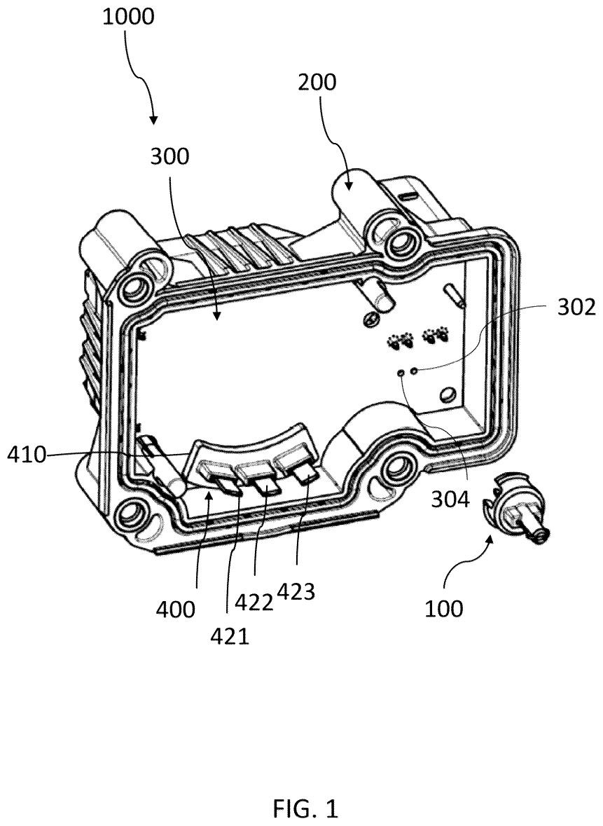

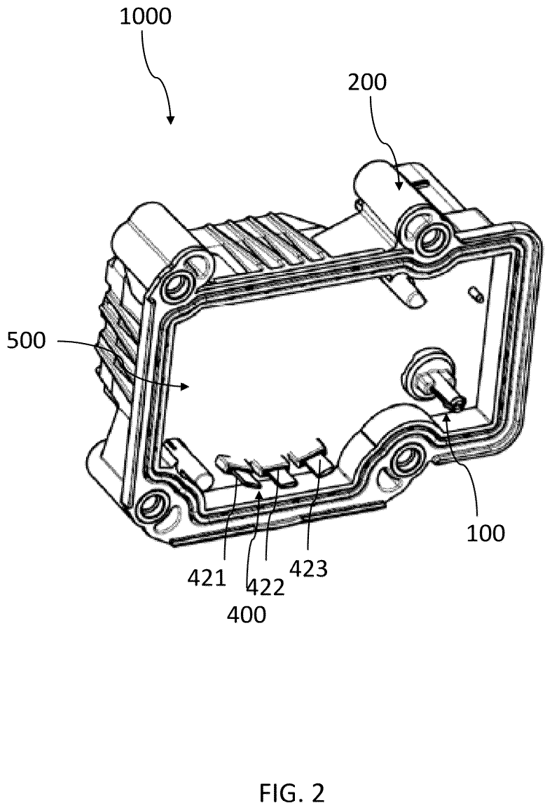

As can be seen in particular in FIG. 2, the circuit board 300 shown in FIG. 1 is configured to be embedded completely in a potting compound 500.

Furthermore, the connector bridge 400 is also embedded in the potting compound 500 in such a way that only an upper portion of the molding 410 still projects out of the potting compound 500. The connector contacts or connectors 421, 422, 423 are configured to make a signal-conducting connection to a corresponding connector contact.

Furthermore, the mass-contact module 100 is at least partly embedded in the potting compound 500. The mass-contact module 100 is configured here only to form an electrically conductive mass contact, which is also referred to as a grounding contact.

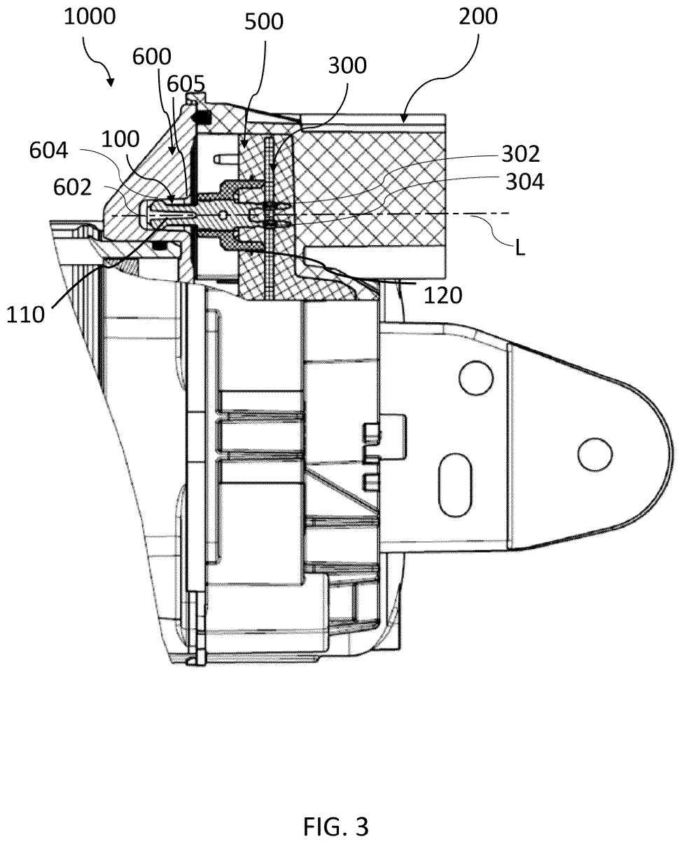

As shown in particular in the partly sectioned side view of the control device 1000 according to FIG. 3, the mass-contact module 100 extends in a longitudinal direction L. The mass-contact module 100 includes here a press-in contact 110 extending in the longitudinal direction L for forming an electrically conductive press-in connection to the circuit board 300 by being pressed into the first receiving opening 302 and the second receiving opening 304. Furthermore, the mass-contact module 100 includes a supporting part 120 which is connected to the press-in contact 110 and is configured to form a force-conducting connection between the circuit board 300 and the press-in contact 110 by forming a form-fitting and/or integral connection to the potting compound 500. The supporting part 120 is partly embedded here in the potting compound 500 by pouring the potting compound 500 into the electronics housing 200. Pouring the potting compound 500 into the electronics housing 200 also causes the embedding of the circuit board 300.

The control device 1000 further includes a diecast housing 600, which forms a cover of the electronics housing 200. The diecast housing 600 includes a hole 602 with a contact surface 604. The contact surface 604 is a metallic contact surface, which is electrically conductively in contact with the press-in contact 110. Thus, the contact surface 604 of the diecast housing 600 is electrically conductively connected to the circuit board 300 via the mass-contact module 100. The mass-contact module 100 is secured against radial forces by the hole 602 which provides the contact surface 604. The hole 602 preferably has an insertion bevel 605 for centering the mass-contact module 100.

As a result of pouring the supporting part 120 into the potting compound 500 and the form-fitting and/or integral connection, which is formed as a result, between the supporting part 120 and the potting compound 500, the press-in contact 110 is fixed securely and any movement of the press-in contact 110 relative to the circuit board 300 is avoided. The press-in contact 110 is firmly connected here to the supporting part 120. The supporting part 120 projects at least partly out of the potting compound 500, so that interfaces between the press-in contact 110 and the potting compound 500 which would permit the penetration of moisture are completely avoided. The single interface between the press-in contact 110 and the potting compound 500 is enclosed in an airtight manner by the supporting part 120, in order to prevent the penetration of moisture.

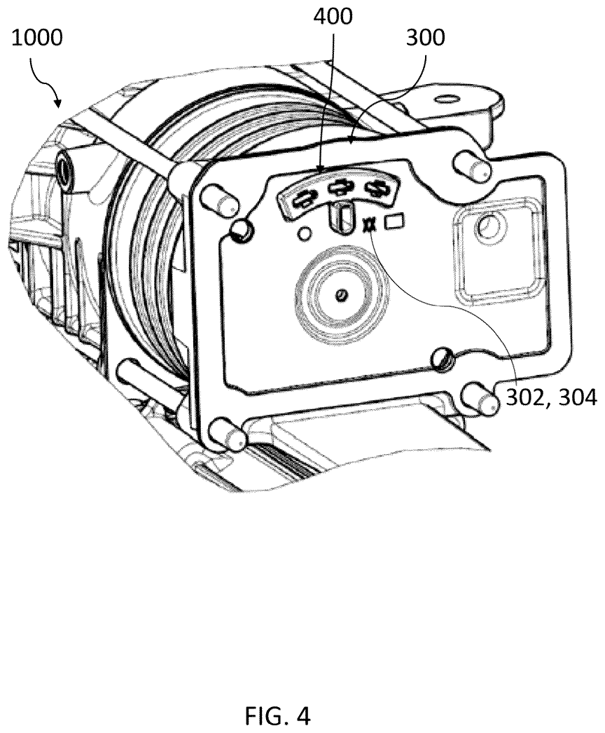

The embodiment of the control device 1000 shown in FIG. 4 differs only in the arrangement of the mass-contact module 100, not shown in the view, and the arrangement of the first receptacle 302 and the second receptacle 304 for forming a press-in connection with the press-in contact 110 (see FIGS. 1 to 3). To this extent, reference is made to the description of the control device 1000 according to FIGS. 1 to 3. The same and similar components have identical designations here. The control device 1000 shown likewise has here a circuit board 300 and a connector bridge 400 connected to the latter.

As in particular the perspective view of a control device 1000 according to FIG. 4 illustrates, the mass-contact module 100 according to the disclosure permits connection to a circuit board 300 at any desired position. Thus, the corresponding receptacles 302, 304, for example, can also be arranged adjacent to the connector bridge 400. The press-in contact 110 (see FIG. 3) here is pushed through the receptacles 302, 304 in the circuit board 300 and, in the mounted state, would project out of the circuit board 300. In the view shown, the electronics housing 200 has been masked out. The connector bridge 400 is likewise pressed into the circuit board 300 and projects out of the bottom of the circuit board, shown in this view. In this form, the circuit board 300 is then pressed into the corresponding electronics housing 200 (see FIG. 3) of the control device 1000 before the potting compound 500 is poured in.

The assembly of the control device 1000 according to FIGS. 1 to 4 includes the connection of the circuit board 300 to the electronics housing 200, for example by a snap-in connection. There then follows the provision of the mass-contact module 100, which, by being pressed into the corresponding receptacles 302, 304 of the circuit board 300, forms an electrically conductive connection. To fix the mass-contact module 100 and to form a force-conducting connection between the circuit board 300 and the press-in contact 110, the potting compound 500 is also poured into the electronics housing 200 to embed the circuit board 300 and the supporting part 120 into the electronics housing 200. The supporting part 120 here makes a form-fitting and/or integral connection to the potting compound 500 to form the force-conducting connection between the circuit board 300 and the press-in contact 110.

FIGS. 5A and 5B show the mass-contact module 100 according to a first embodiment. The mass-contact module 100 has a press-in contact 110 extending in a longitudinal direction L and having a connector portion 111 for forming an electrically conductive press-in connection to the circuit board 300 (see FIGS. 1 to 4) and an end portion 114 which is at a distance in the longitudinal direction L. As shown in FIG. 3, the end portion 114 is configured for contact with a contact surface 604. The press-in contact 110 has the connector section 111, preferably with a first pin 112 and a second pin 113 for forming a press-in connection to the circuit board 300.

Furthermore, the mass-contact module 100 has a supporting part 120 connected to the press-in contact 110. As shown in FIG. 3, the supporting part 120 is configured to form a force-conducting connection between the circuit board 300 and the press-in contact 110 by forming a form-fitting and/or integral connection to the potting compound 500.

The supporting part 120 preferably has a guide portion 121. The guide portion 121 extends from a central area of the press-in contact 110 to the end portion 114. The end portion 114 has a first leg 116 and a second leg 118, which are movable or elastically deformable relative to each other in a direction orthogonal to the longitudinal direction L. The movement or deformation of the legs 116, 118 is guided here by the guide portion 121.

The supporting part 120 further has an anchoring portion 122, which extends from the guide portion 121 to the connector portion 111. The anchoring portion 122 has a diameter that is larger than the guide portion 121. The supporting part 120 is configured to be embedded in the potting compound 500, at least in the area of the anchoring portion 122.

The anchoring section 122 projects in particular partly with respect to the guide portion 121 transversely to the longitudinal direction L in such a way that a form-fitting connection between the anchoring portion 122 and the potting compound 500 is formed (see FIG. 3).

Formed in the area of the guide portion 121, in particular in the area of the first and second leg 116, 118 is a guide opening 123, in which the legs 116, 118 are movably accommodated. The guide opening 23 lies in the section plane of FIG. 5A and is therefore only indicated.

The supporting part 120 also has a press-in opening 124, into which the press-in contact 110 is pressed. To better anchor the press-in contact 110 in the press-in opening 124, the press-in contact 110 has a number of retaining elements 119, which are configured to permit a movement of the press-in contact 110 in a press-in direction E and to prevent a movement counter to the press-in direction E.

FIGS. 6A and 6B show a second embodiment of the mass-contact module 100. The mass-contact module 100, as well as the mass-contact module shown in FIGS. 5A and 5B, has a press-in contact 110 extending in a longitudinal direction L, the configuration of which corresponds to the press-in contact shown in FIGS. 5A and 5B. To this extent, reference is made to the above description of the press-in contact 110.

Furthermore, the mass-contact module 100 has a supporting part 120 which is connected to the press-in contact 110 and is configured to form a force-conducting connection between the circuit board 300 (see FIGS. 1 to 3) and the press-in contact 110 by forming a form-fitting and preferably also integral connection to the potting compound 500 (see FIGS. 1 to 3).

The supporting part 120 has an anchoring portion 122, which is connected to the press-in contact 110 between the end portion 114 and the connector section 111. As, in particular, FIG. 6A shows, the press-in contact 110 has a number of retaining elements 119 in the central area, which are configured to prevent the press-in contact 110 detaching from the supporting part 120.

The supporting part 120 has an anchor plate 126, from which a retaining portion 129 with a constant diameter extends in the direction of the end portion 114. The retaining section 129 has a number of force introduction elements 128. The force introduction elements 128 extend from the anchor plate 126 along the retaining portion 129 in the direction of the end portion 114. Seen in the longitudinal direction L, the force introduction elements 128 are thus arranged between the anchor plate 126 and the end portion 114. The force introduction elements 128 are configured to conduct forces from the retaining portion 129, in particular the end portion 114 of the press-in contact 110, into the anchor plate 126. The anchor plate 126 is configured to be potted completely in a potting compound 500 (see FIGS. 1 to 3) for the force-fitting connection of the press-in contact 110 to a circuit board 300. Via the cross section of the anchor plate 126 enlarged as compared with the retaining section 129 in a plane orthogonal to the longitudinal direction L, the introduction of force is improved.

The force introduction elements 128 are formed obliquely with respect to the longitudinal direction L, wherein the outer edge of the force introduction elements 128 comes close to the retaining section 129 in the direction of the end portion 114.

A corresponding supporting part 120 is preferably produced from a thermoplastic, in particular polybutylene terephthalate or polyamide, that is, a hard-elastic plastic. These can preferably be produced in an injection molding process, wherein the configuration of the force introduction elements 128 and the anchor plate 126 advantageously permit production in the injection molding process.

Particularly preferably, the supporting part includes a fiber-reinforced thermoplastic having a fiber proportion of at least 10%, preferably 20%. The reinforcing fibers are in particular glass fibers. Also in the embodiment shown in FIGS. 6A and 6B, the press-in contact 110 is pressed into the press-in opening 124 of the supporting part 120 in a press-in direction E. The retaining elements 119 prevent any movement of the press-in contact counter to the press-in direction E by engaging in the corresponding wall of the supporting part 120.

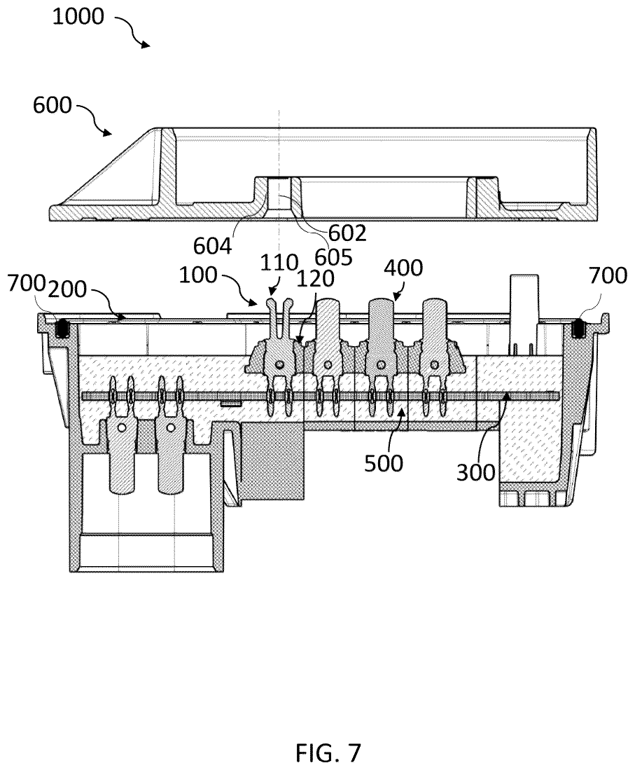

FIG. 7 shows a further embodiment of a control device 1000. The control device 1000 includes an electronics housing 200, in which a circuit board 300 is accommodated. The electronics housing 200 can be closed via a diecast housing 600. The control device 1000 has a mass-contact module 100 for the electrically conductive connection of the circuit board 300 to a contact surface 604 formed in a hole 602. The mass-contact module 100 thus provides a grounding contact for the circuit board 300. The mass-contact module 100 is formed integrally on a connector bridge 400. The circuit board 300 is embedded in a potting compound 500. Furthermore, the connector bridge 400, including the mass-contact module 100, is also at least partly embedded in the potting compound 500. The mass-contact module 100 is configured substantially identically to the mass-contact module shown in FIGS. 6A and 6B. It has a press-in contact 110 and a supporting part 120 in a known way.

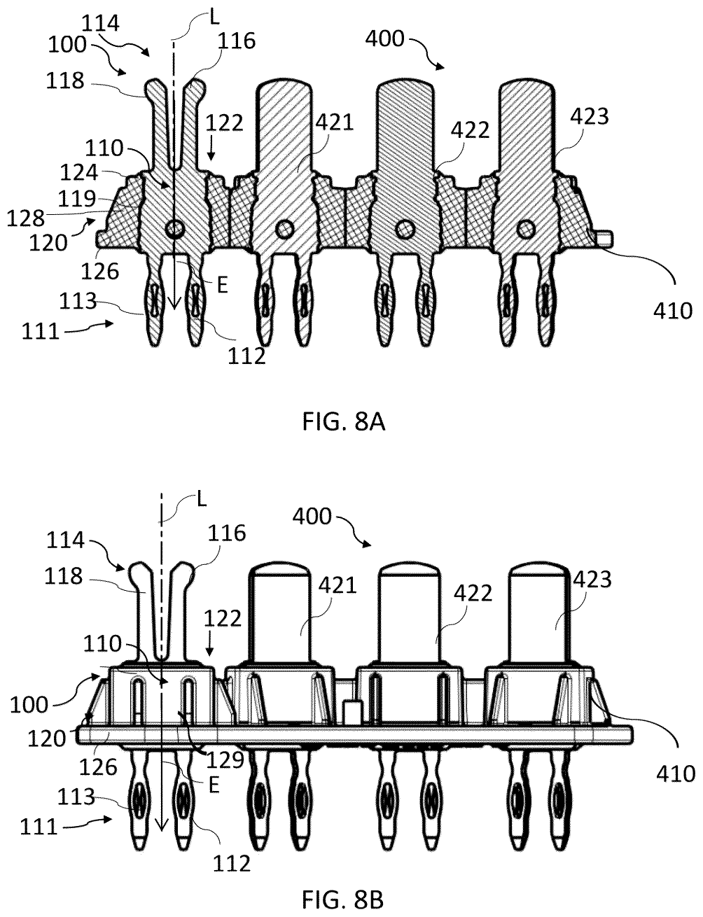

As shown in detail in FIGS. 8A and 8B, the connector bridge 400 has a first connector 421, a second connector 422 and a third connector 423, which are accommodated in a molding 410. The supporting part 120 is connected to the molding 410. The connection can be made here both integrally, for example by producing the supporting part 120 together with the molding 410 in an injection molding process, or else by joining methods, such as for example plastic welding or adhesive bonding.

The diecast housing 600 has an insertion bevel 605 at the opening of the hole 602. The insertion bevel 605 is configured to center the mass-contact module 100. The hole 602 is formed in the diecast housing 600 so as to correspond to the arrangement of the mass-contact module 100. As a result of the insertion bevel 605, the hole 602 has an enlarged diameter on the opening side. The legs 116, 118 of the press-in contact 110 and in particular of the connector portion 111 come into contact with the insertion bevel 605 and are pressed against each other by the latter as the diecast housing 600 is placed on the electronics housing 200. In a state in which the diecast housing 600 completely closes the electronics housing 200, the legs 116, 118 are accommodated completely in the hole 602 and are electrically conductively in contact with the contact surface 604.

In the area of the connectors 421, 422, 423, the diecast housing 600 has a recess which permits the connection of the connectors 421, 422, 423 to further connector contacts for the signal transmission.

The control device 1000 additionally has a seal 700, which preferably extends continuously along the electronics housing 200 in a receiving groove 201, in order to seal off the interior of the housing when the control device 1000 is closed.

As FIGS. 8A and 8B further show in detail, the mass-contact module 100, analogous to the embodiment shown in FIGS. 6A and 6B, has a press-in contact 110 extending in a longitudinal direction L. Furthermore, the mass-contact module 100 has a supporting part 120 which is connected to the press-in contact 110 and is configured to form a force-conducting connection between the circuit board 300 (see FIGS. 1 to 3) and the press-in contact 110 by forming a form-fitting and preferably also integral connection to the potting compound (see FIGS. 1 to 3).

The supporting part 120 has an anchoring portion 122, which is connected to the press-in contact 110 between the end portion 114 and the connector portion 111. As shown in particular by FIG. 8A, the press-in contact 110 has a number of retaining elements 119 in the central area, which are configured to prevent the press-in contact 110 from detaching from the supporting part 120.

The supporting part 120 has an anchor plate 126, from which a retaining portion 129 with a constant diameter extends in the direction of the end portion 114. The retaining section 129 has a number of force introduction elements 128, which extend from the anchor plate 126 along the retaining section 129 in the direction of the end portion 114. Seen in the longitudinal direction L, the force introduction elements 128 are thus arranged between the anchor plate 126 and the end portion 114. The force introduction elements 128 are configured to conduct forces from the retaining section 129 and in particular the end portion 114 of the press-in contact 110 into the anchor plate 126. The anchor plate 126 is configured to be potted completely in a potting compound 500 for the force-fitting connection of the press-in contact 110 to a circuit board 300.

The force introduction elements 128 are formed obliquely with respect to the longitudinal direction L, wherein the outer edge of the force introduction elements 128 comes close to the retaining section 129 in the direction of the end portion 114. Such a supporting part 120 is preferably produced from a thermoplastic, in particular polybutylene terephthalate or polyamide, that is, a hard-elastic plastic. These can preferably be produced in an injection molding process. Particularly preferably, the supporting part includes a fiber-reinforced thermoplastic with a fiber proportion of at least 10%, preferably 20%. The reinforcing fibers are in particular glass fibers. In the embodiment shown in FIGS. 8A and 8B, the press-in contact 110 is also pressed into the press-in opening 124 of the supporting part 120 in a press-in direction E. The retaining elements 119 prevent a movement of the press-in contact counter to the press-in direction E by engaging in the corresponding wall of the supporting part 120. At least one specification heading is required.

It is understood that the foregoing description is that of the preferred embodiments of the invention and that various changes and modifications may be made thereto without departing from the spirit and scope of the invention as defined in the appended claims.

### LIST OF DESIGNATIONS (PART OF THE DESCRIPTION)

1000 Control device
100 Mass-contact module
110 Press-in contact
111 Connector portion
112 First pin
113 Second pin
114 End portion
116 First leg
118 Second leg
119 Retaining elements
120 Supporting part
121 Guide portion
122 Anchoring portion
123 Guide opening
124 Press-in opening
126 Anchor plate
128 Force introduction element
129 Retaining portion
200 Electronics housing
300 Circuit board
302 First receptacle
304 Second receptacle
400 Connector bridge
410 Molding
421 First connector
422 Second connector
423 Third connector
500 Potting compound
600 Diecast housing
602 Opening
604 Contact surface
605 Insertion bevel
L Longitudinal direction
E Press-in direction

1. A mass-contact module for a control device, the mass-contact module comprising:
a press-in contact extending in a longitudinal direction;
said press-in contact having a connector portion for forming an electrically conductive press-in connection to a circuit board and an end portion which is at a distance in the longitudinal direction and is configured to make contact with a contact surface; and,
a supporting part connected to said press-in contact and configured to form a force-conducting connection between the circuit board and said press-in contact by forming at least one of a form-fitting and an integral connection to a potting compound.

2. The mass-contact module of claim 1, wherein said supporting part has a guide portion and an anchoring portion projecting with respect to said guide portion transversely to the longitudinal direction; and, said guide portion is configured to connect to said press-in contact; and, said anchoring portion is configured for the form-fitting connection to the potting compound.

3. The mass-contact module of claim 2, wherein said anchoring portion has an anchor plate and at least one force introduction element arranged between said anchor plate and said end portion.

4. The mass-contact module of claim 1, wherein said supporting part is formed integrally with a connector bridge.

5. The mass-contact module of claim 1, wherein said supporting part includes a thermoplastic.

6. The mass-contact module of claim 5, wherein said thermoplastic is a fiber-reinforced thermoplastic with a fiber proportion of at least 10%.

7. The mass-contact module of claim 1, wherein said supporting part is an electrical insulator.

8. The mass-contact module of claim 1, wherein said end portion has a first leg and a second leg which extend in the longitudinal direction and are movable or elastically deformable relative to one another transversely to the longitudinal direction in order in each case to come into contact with a contact surface.

9. The mass-contact module of claim 8, wherein said supporting part has a guide portion and an anchoring portion projecting with respect to said guide portion transversely to the longitudinal direction; and, said guide portion is configured to connect to said press-in contact; said anchoring portion is configured for the form-fitting connection to the potting compound; and, said guide portion has a guide opening which extends in the longitudinal direction and in which said first leg and said second leg are accommodated such that they can move transversely to the longitudinal direction.

10. The mass-contact module of claim 1, wherein said supporting part has a press-in opening and said press-in contact is configured to be connected to said supporting part by being pressing into said press-in opening in a press-in direction.

11. The mass-contact module of claim 1, wherein said press-in contact has a plurality of retaining elements configured to prevent any movement of said press-in contact relative to said supporting part counter to a press-in direction.

12. The mass-contact module of claim 1, wherein said press-in contact is configured to be connected to said supporting part by pressing-in via ultrasonic embedding.

13. The mass-contact module of claim 1, wherein said supporting part is produced by an injection molding process, in which the press-in contact is laid in an injection molding tool; and, said press-in contact is overmolded for the production of said supporting part and the connection to said supporting part.

14. The mass-contact module of claim 1, wherein said supporting part includes a polybutylene terephthalate or polyamide.

15. The mass-contact module of claim 5, wherein said thermoplastic is a fiber-reinforced thermoplastic with a fiber proportion of at least 20%.

16. A control device for a motor vehicle, the control device comprising:
an electronics housing;
a circuit board arranged in said electronics housing;
a potting compound in which said circuit board is embedded;
a metallic contact surface;
at least one mass-contact module for the electrically conductive connection of said circuit board to said metallic contact surface;
said at least one mass-contact module including a press-in contact extending in a longitudinal direction and a supporting part;
said press-in contact having a connector portion for forming an electrically conductive press-in connection to a circuit board and an end portion which is at a distance in the longitudinal direction and is configured to make contact with a contact surface; and,
said supporting part being connected to said press-in contact and configured to form a force-conducting connection between said circuit board and said press-in contact by forming at least one of a form-fitting and an integral connection to a potting compound.

17. The control device of claim 16, wherein said electronics housing defines a hole with a wall which forms said contact surface and an insertion bevel configured to center said mass-contact module.

18. The control device of claim 16, wherein said potting compound includes at least one of a thermosetting plastic and polyurethane.

19. The control device of claim 16, wherein said potting compound is configured to form-fit and integrally connect to said supporting part.

20. An assembly method for assembling a control device for a motor vehicle, the assembly method comprising:
connecting a circuit board to an electronics housing;
providing at least one mass-contact module having a press-in contact extending in a longitudinal direction and a supporting part, wherein the press-in contact has a connector portion for forming an electrically conductive press-in connection to the circuit board and an end portion which is at a distance in the longitudinal direction and is configured to make contact with a contact surface, wherein the supporting part is connected to the press-in contact and configured to form a force-conducting connection between the circuit board and the press-in contact by forming at least one of a form-fitting and an integral connection to a potting compound;
pressing the press-in contact of the mass-contact module into a corresponding opening in the circuit board for forming an electrically conductive connection; and,
pouring the potting compound into the electronics housing to embed the circuit board, wherein the supporting part is at least partly embedded by the potting compound to form a force-conducting connection between the circuit board and the press-in contact.
